(19) United States
(12) Patent Application Publication
(10) Pub. No.: US 2025/0006570 A1
(43) Pub. Date: Jan. 2, 2025

(54) GLASS CORES INCLUDING MULTIPLE LAYERS AND RELATED METHODS

(71) Applicant: Intel Corporation, Santa Clara, CA (US)

(72) Inventors: Gang Duan, Chandler, AZ (US); Srinivas Venkata Ramanuja Pietambaram, Chandler, AZ (US); Jeremy Ecton, Gilbert, AZ (US); Brandon Christian Marin, Gilbert, AZ (US)

(73) Assignee: Intel Corporation, Santa Clara, CA (US)

(21) Appl. No.: 18/883,851

(22) Filed: Sep. 12, 2024

(51) Int. Cl. H01L 23/15; H01L 23/00; H01L 23/31; H01L 23/373; H01L 23/498; H01L 23/538; H01L 25/065

(52) U.S. Cl. CPC H01L 23/15; H01L 23/3128; H01L 23/373; H01L 23/49827; H01L 23/5383; H01L 24/16; H01L 24/17; H01L 24/24; H01L 25/0652; H01L 25/0655; H01L 2224/16227; H01L 2224/1703; H01L 2224/24226

(57) ABSTRACT

Glass cores including multiple layers and related methods are disclosed. An apparatus disclosed herein includes a printed circuit board and an integrated circuit package coupled to the printed circuit board, the integrated circuit package including a die and a glass core including a first layer having a first coefficient of thermal expansion and a second layer having a second coefficient of thermal expansion different than the first coefficient of thermal expansion.

### BACKGROUND

In many electronic devices, semiconductor chips and/or dies (e.g., integrated circuit (IC) chips) are connected to larger circuit boards such as motherboards and/or other types of printed circuit boards (PCBs). Frequently, the IC chips are contained in a package that includes a package substrate with one or more redistribution layers containing metal interconnects that enable electrical connections between contacts on the IC chips and corresponding contacts on PCBs.

### BRIEF DESCRIPTION OF THE DRAWINGS

FIG. 1 is a cross-sectional side view of an example implementation of an integrated circuit (IC) package including a glass core constructed in accordance with teachings of this disclosure.

FIG. 2 is a cross-sectional side view of an example first IC package including an example first glass core that can implement the glass core of FIG. 1.

FIG. 3 is a cross-sectional side view of an example second IC package including an example second glass core that can implement the glass core of FIG. 1.

FIG. 4 is a cross-sectional side view of an example third IC package including an example third glass core that can implement the glass core of FIG. 1.

FIG. 5 is a cross-sectional side view of an example fourth IC package including an example fourth glass core that can implement the glass core of FIG. 1.

FIGS. 6, 7, 8, 9, 10, 11, 12, 13, and 14 are cross-sectional views depicting a glass core implemented in accordance with teachings of this disclosure in various stages of a manufacturing process.

FIG. 15 is a flowchart representative of an example manufacturing process for manufacturing the glass core of FIGS. 6-14.

FIG. 16 is a top view of a wafer and dies that may be included in an IC package constructed in accordance with teachings disclosed herein.

FIG. 17 is a cross-sectional side view of an IC device that may be included in an IC package constructed in accordance with teachings disclosed herein.

FIG. 18 is a cross-sectional side view of an IC device assembly that may include an IC package constructed in accordance with teachings disclosed herein.

FIG. 19 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In recent years, glass has been increasingly investigated as a core material for the package substrates of integrated circuit packages. The rigidness of glass cores reduces the warpage experience of glass cores and enables package substrates to have increased input/output density. Glass cores can be formed with low total thickness variation and tunable optical properties. While glass cores offer many advantages when compared to other core materials, the fragility of glass causes glass cores to be susceptible to damage during the manufacturing and operation of IC packages including such glass cores. In some such examples, stress applied to the glass core, such as stress associated with the thermal expansion of other components of the package, can cause cracks to propagate through the core. This cracking can cause the glass core to split (referred to herein as “seware”), which can result in the scrapping of the substrate package including the glass core.

Examples disclosed herein include integrated circuit packages that include unibody glass cores with multiple layers having different coefficients of thermal expansion (CTE). Examples disclosed herein include glass cores with vertically arranged layers with different coefficients of thermal expansion. An example glass core disclosed herein includes a first layer proximate to the die(s) of the integrated circuit package with a coefficient of thermal expansion approximately equal to the coefficient of thermal expansion of the dies and a second layer proximate to the circuit board with a coefficient of thermal expansion approximately equal to the coefficient of thermal expansion of the circuit board. Some such glass cores disclosed herein include intermediate layers between the first layer and the second layer. An example glass core disclosed herein includes a plurality of layers that define a CTE gradient between an upper surface of the glass core and a bottom surface of the glass core. Example methods for manufacturing glass cores disclosed herein enable the embedding of components, such as interconnect bridges, within the glass cores and the deposition of liners on interconnects extending through the glass cores. Examples disclosed herein reduce thermal stresses experienced by glass cores, which mitigates the likelihood of seware and singulation defects experienced by the glass cores.

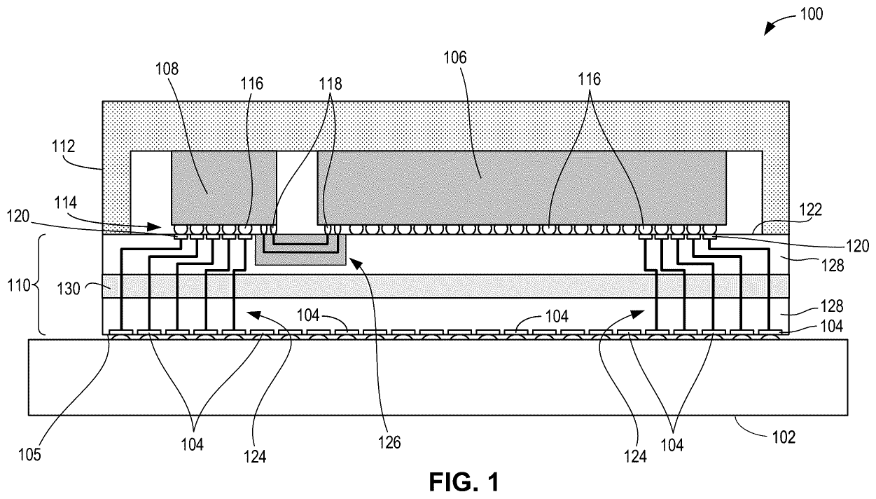

FIG. 1 illustrates an example integrated circuit (IC) package 100 constructed in accordance with teachings disclosed herein. In the illustrated example, the IC package 100 is electrically coupled to a substrate 102 via an array of contact pads 104 (e.g., lands, etc.) on a mounting surface 105 (e.g., a bottom surface) of the package. In some examples, the substrate 102 can be implemented by a package substrate or a printed circuit board (PCB). In some examples, the IC package 100 may include balls, pins, and/or pads, in addition to or instead of the contact pads 104, to enable the electrical coupling of the IC package 100 to the substrate 102. In this example, the IC package 100 includes an example first die 106 (e.g., a silicon die, a semiconductor die, etc.) and an example second die 108 that is mounted to a package substrate 110 and enclosed by a package lid 112 (e.g., a mold compound, etc.). Thus, the package substrate 110 is an example means for supporting a semiconductor die. While the example IC package 100 of FIG. 1 includes the dies 106, 108, in other examples, the IC package 100 may include additional dies or only one die. In some examples, some or all of the dies 106, 108, or a separate die are embedded in the package substrate 110. The dies 106, 108 can provide any suitable type of functionality (e.g., data processing, memory storage, etc.). In some examples, one or both of the dies 106, 108 are implemented by a die package including multiple dies arranged in a stacked formation. For example, the die 108 can include a stack of Dynamic Random Access Memory (DRAM) die arranged on top of a memory controller die to form a memory die stack.

In the illustrated example of FIG. 1, the dies 106, 108 are electrically and mechanically coupled to the package substrate 110 via corresponding arrays of interconnects 114. In the illustrated example of FIG. 1, the interconnects 114 are bumps. The interconnects 114 can include solder joints, micro bumps, combinations of metallic (e.g., copper) pillars and solder, etc. In other examples interconnects 114 may comprise directly bonded or “hybrid bonded” metallic interconnects. In other examples, the interconnects 114 can be implemented any other type of electrical connection in addition to or instead of the bumps shown (e.g., balls, pins, pads, wire bonding, etc.). The electrical connections between the dies 106, 108 and the package substrate 110 (e.g., the interconnects 114, etc.) are referred to herein as “first level interconnects.” The electrical connections between the IC package 100 and the substrate102 (e.g., the contact pads 104, etc.) are referred to herein as “second level interconnects.” In some examples, one or both the dies 106, 108 are stacked on top of one or more other dies and/or an interposer. In some such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pillars, pins, pads, wire bonding, etc.) between a die and a package substrate or between a die and an underlying die and/or interposer.

In the illustrated example of FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. That is, as shown in the illustrated example, when the dies 106, 108 are mounted to the package substrate 110, the core bumps 116 are physically connected and electrically coupled to contact pads 120 on an inner surface 122 of the package substrate 110. The contact pads 120 on the inner surface 122 of the package substrate 110 are electrically coupled to the contact pads 104 on the mounting surface 105 of the package substrate 110 (e.g., a surface opposite the inner surface 122, an external bottom surface, etc.) via internal interconnects 124 within the package substrate 110. As a result, there is a continuous electrical signal path between the interconnects 114 and the contacts pads 104 mounted to the substrate 102 that pass through the contact pads 120 and the internal interconnects 124 provided therebetween.

As used herein, the bridge bumps 118 are bumps on the dies 106, 108 through which electrical signals pass between different ones of the dies 106, 108 within the IC package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the contact pads 104 on the mounting surface 105 and the contact pads on the inner surface 122. However, in some examples, the internal interconnects 124 are defined by traces or routing in separate conductive (e.g., metal) layers within build-up regions 128 on one or both sides of a glass core 130 (e.g., the hybrid core, etc.) in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the glass core 130.

In the illustrated example of FIG. 1, the substrate 110 of the example IC package 100 includes an example glass core 130. In the illustrated example of FIG. 1, the glass core 130 includes a plurality of layers (not depicted in FIG. 1) having different coefficients of thermal expansion. In some examples, the layers of the glass core 130 include (e.g., are composed of, etc.) at least one of: aluminosilicate, borosilicate, alumino-borosilicate, silica, and/or fused silica. In some examples, the layers of the glass core 130 include one or more additives including: aluminum oxide (Al₂O₃), boron trioxide (B₂O₃), magnesia oxide (MgO), calcium oxide (CaO), stoichiometric silicon oxide (SiO), barium oxide (BaO), stannic oxide (SnO₂), nickel alloy (Na₂O), potassium oxide (K₂O), phosphorus trioxide (P₂O₃), zirconium dioxide (ZrO₂), lithium oxide (Li₂O), titanium (Ti), and/or zinc (Zn). In some examples, the layers of the glass core 130 include silicon and oxygen. In some examples, the glass core 130 includes silicon, oxygen, and/or one or more of aluminum, boron, magnesium, calcium, barium, tin, sodium, potassium, strontium, phosphorus, zirconium, lithium, titanium, and/or zinc. In some examples, the glass core 130 includes at least 23 percent silicon by weight and at least 26 percent oxygen by weight. In some examples, the layers of the glass core 130 includes silicon, oxygen, and aluminum. In some examples, the layers of the glass core 130 include at least 23 percent silicon by weight, at least 26 percent oxygen by weight, and at least 5 percent aluminum by weight. In some examples, the coefficients of thermal expansion of each of the layers of the glass core 130 can be tuned by tailoring (e.g., varying, changing, etc.) the composition of the glass of each of the layers. For example, the coefficients of thermal expansion of each of the layers of the glass core 130 can be tailored by varying the relative proportions of Al₂O₃, B₂O₃, Li₂O, Na₂O, K₂O, Sb₂O₃, and/or other additives in each of the layers and/or via processing variations (e.g., lamination cladding, thermal treatment, etc.).

In some examples, each layer of the glass core 130 is an amorphous solid glass layer. In some examples, each layer of the glass core 130 is a layer of glass that does not include an organic adhesive or an organic material. In some examples, each layer of the glass core 130 is a solid layer of glass having a rectangular shape in plan view. In some examples, the glass core 130 includes at least one glass layer and does not include epoxy and does not include glass fibers (e.g., does not include an epoxy-based prepreg layer with glass cloth). In some examples, the glass core 130 has a rectangular shape that is substantially coextensive, in plan view, with the layers (e.g., the build-up regions 128, etc.) above and/or below the core. In some examples, the glass core 130 has a thickness in a range of about 50 micrometers (μm) to about 1.4 millimeters (mm). In some examples, the glass core 130 has dimensions of about 10 mm on a side to about 250 mm on a side (e.g., 10 mm by 10 mm to 250 mm by 250 mm). In some examples, the glass core 130 corresponds to a rectangular prism volume with sections (e.g., vias) removed and filled with other materials (e.g., metal).

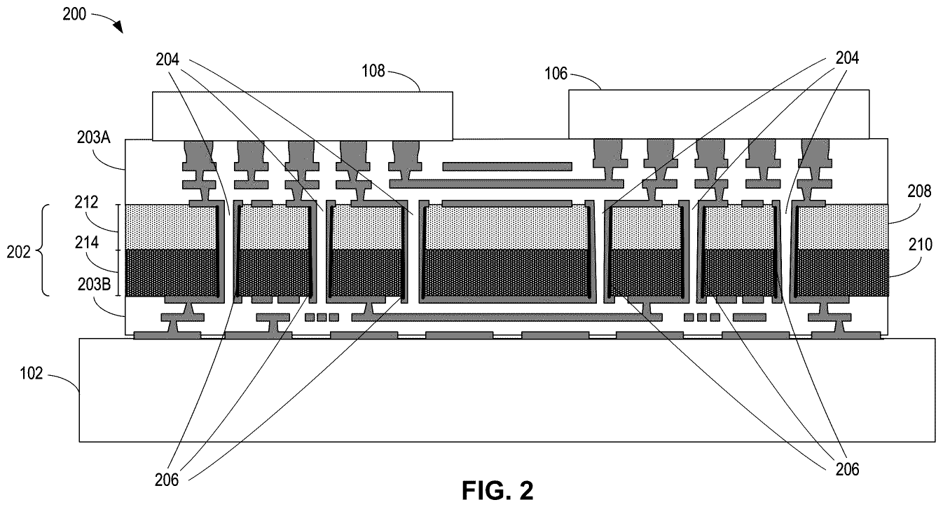

FIG. 2 is a cross-sectional side view of an example first IC package 200 that can implement the IC package 100 of FIG. 1. In the illustrated example of FIG. 2, the IC package 200 includes an example first glass core 202. In the illustrated example of FIG. 2, the IC package 200 includes the dies 106, 108 of FIG. 1 and is coupled to the substrate 102 of FIG. 1. In the illustrated example of FIG. 2, the IC package 200 includes an example first build-up region 203A and an example second build-up region 203B. In the illustrated example of FIG. 2, the first build-up region 203A is between the dies 106, 108 and the first glass core 202 and the second build-up region 203B is between the substrate 102 and the first glass core 202. The build-up regions 203A, 203B are similar to the build-up regions 128 of FIG. 1, except as noted otherwise. In the illustrated example of FIG. 2, the IC package 200 includes example through glass vias (TGVs) 204, which have corresponding example liners 206. In the illustrated example of FIG. 2, the first glass core 202 includes an example first layer 208 (also referred to herein as a first region) and an example second layer 210 (also referred to herein as a second region). In the illustrated example of FIG. 2, the first layer 208 has an example first thickness 212 and the second layer 210 has an example second thickness 214.

In the illustrated example of FIG. 2, the TGVs 204 are interconnects that extend between the build-up regions 203A, 203B through the first glass core 202. The TGVs 204 enable the signals and power to be transmitted through the first glass core 202. In the illustrated example of FIG. 2, the integrated circuit package 200 includes liners 206, which are between the TGVs 204 of the glass core 202. The liners 206 insulate the TGVs 204, reduce crosstalk between ones of the TGVs 204, and mitigate damage thereto during the manufacturing of the first IC package 200 (e.g., cracking of the glass surrounding the TGVs 204, etc.). In some examples, the liners 206 include (e.g., are composed of, etc.) a polymer (e.g., an epoxy, etc.). In some examples, the liners 206 can be deposited on the TGVs 204 via a vapor deposition process (e.g., physical vapor deposition (PVD), chemical vapor deposition (CVD), atomic layer deposition (ALD), etc.). In other examples, the liners 206 can be deposited via another deposition process (e.g., lithography, plating, sputtering, etc.).

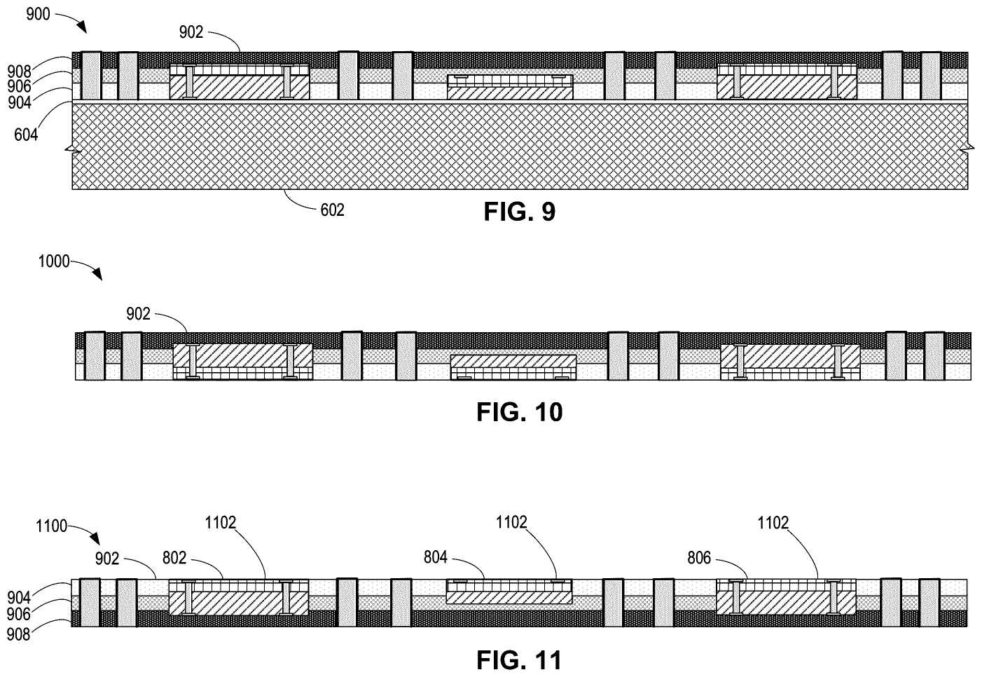

In the illustrated example of FIG. 2, the glass core 202 does not include embedded components. In other examples, the glass core 202 can include one or more embedded components, such as deep trench capacitors (DTCs), embedded multi-die interconnect bridges (EMIBs), an embedded inductor, a different type of embedded die, etc. An example glass core implemented in accordance with teachings of this disclosure including embedded components is described below in conjunction with FIG. 9.

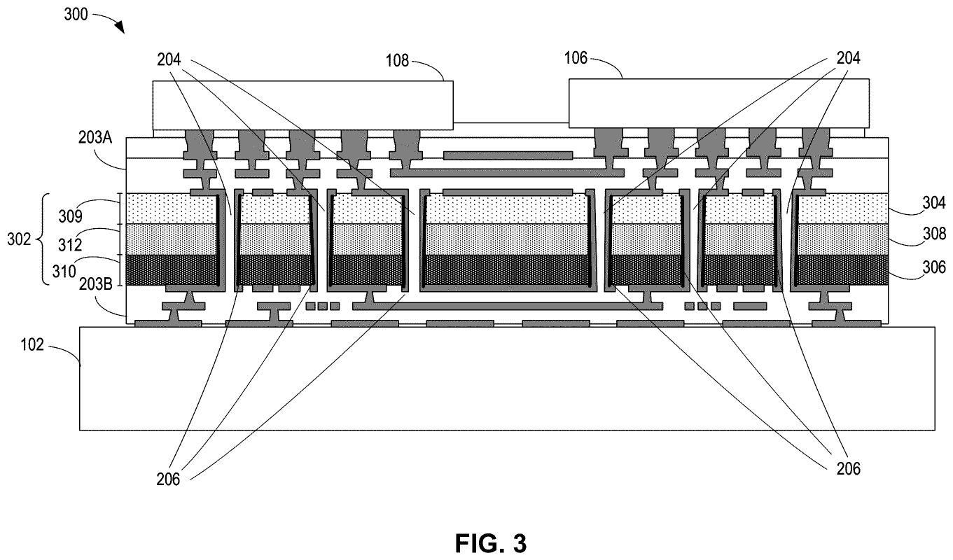

In the illustrated example of FIG. 2, the first layer 208 has the first thickness 212 and the second layer 210 has the second thickness 214. In the illustrated example of FIG. 2, the first thickness 212 is equal to (e.g., approximately equal to, etc.) the second thickness 214. In other examples, the first thickness 212 is different than the second thickness 214. For example, the first thickness 212 can be greater than the second thickness 214 or the second thickness 214 can be greater than the first thickness 212. In the illustrated example of FIG. 2, the sum of the thicknesses 212, 214 is the total thickness of the glass core 202. In other examples, the glass core 202 includes one or more intermediate layers between the first layer 208 and the second layer 210. For example, the glass core 202 can include one or more other glass layers between the layers 208, 210. Example glass cores including more than two layers of glass are described below in conjunction with FIGS. 3-5. Additionally or alternatively, the glass core 202 can include one or more other layers (e.g., insulator layers, build-up layers, bonding layers, etc.) between the first layer 208 and second layer 210.

In the illustrated example of FIG. 2, the first layer 208 abuts (e.g., is in direct contact with, etc.) the second layer 210. That is, the bottom surface of the first layer 208 abuts the top surface of the second layer 210. In the illustrated example of FIG. 2, the first layer 208 is proximate to the dies 106, 108 and the second layer 210 is proximate to the substrate 102 (e.g., the first layer 208 is closer to the dies 106, 108 than the second layer 210 is, the second layer 210 is closer to the substrate 102 than the first layer 208 is, the first layer 208 is distal to the substrate 102, the second layer 210 is distal to the dies 106, 108, etc.). That is, based on the orientation of the example first IC package 200 in FIG. 2, the first layer 208 is above the second layer 210 (e.g., the second layer 210 is below the first layer 208, etc.). In the illustrated example of FIG. 2, the top surface of the first layer 208 abuts (e.g., directly contacts, etc.) the first build-up region 203A and the bottom surface of the second layer 210 abuts (e.g., directly contacts, etc.) the second build-up region 203B. In other examples, one or more intermediate layers are between corresponding ones of the build-up regions 203A, 203B and the layers 208, 210.

In the illustrated example of FIG. 2, the first layer 208 has a coefficient of thermal expansion that is different than the coefficient of thermal expansion of the second layer 210. For example, the first layer 208 can have a coefficient of thermal expansion that is less than the coefficient of thermal expansion of the second layer 210. In some examples, the first layer 208 includes a glass composition with a coefficient of thermal expansion approximately equal to the coefficient of thermal expansion of the dies 106, 108 (e.g., the coefficient of thermal expansion of silicon, etc.) and the second layer 210 has a glass composition with a coefficient of thermal expansion approximately equal to the coefficient of thermal expansion of the substrate102 (e.g., the coefficient of thermal expansion of copper and/or laminate epoxy, etc.). In some such examples, the thermal expansion of the first layer 208 is approximately 3E-6 Kelvin⁻¹ and the coefficient of thermal expansion of the second layer 210 is approximately 20E-6 Kelvin⁻¹. In other examples, the first layer 208 has a greater coefficient of thermal expansion than the second layer 210.

FIG. 3 is a cross-sectional side view of an example second integrated circuit package 300 that can implement the IC package 100 of FIG. 1. In the illustrated example of FIG. 3, the second IC package 300 includes an example second glass core 302. In the illustrated example of FIG. 3, the second IC package 300 includes the dies 106, 108 of FIG. 1 and is coupled to the substrate102 of FIG. 1. In the illustrated example of FIG. 3, the second IC package 300 includes the build-up regions 203A, 203B of FIG. 2, the TGVs 204 of FIG. 2, and the liners 206 of FIG. 2. In the illustrated example of FIG. 2, the second glass core 302 includes an example first layer 304 (also referred to herein as a first region), an example second layer 306 (also referred to herein as a second region), and an example third layer 308 (also referred to herein as a third region).

In the illustrated example of FIG. 3, the first layer 304 has an example first thickness 309, the second layer 306 has an example second thickness 310, and the third layer 308 has an example third thickness 312. In the illustrated example of FIG. 3, the thicknesses 309, 310, 312 are equal (e.g., approximately equal, etc.). In other examples, the thicknesses 309, 310, 312 are not equal. For example, the third thickness 312 can be greater than the first thickness 309 and the second thickness 310. In other examples, the thicknesses 309, 310, 312 can have other suitable magnitude(s). In the illustrated example of FIG. 3, the sum of the thicknesses 309, 310, 312 is the total thickness of the second glass core 302. In other examples, the second glass core 302 can include one or more intermediate layers between the layers 304, 306, 308. For example, the second glass core 302 can include one or more other layers between the first layer 304 and the third layer 308 and/or one or more other layers between the second layer 306 and the third layer 308 (e.g., glass layers, insulator layers, build-up layers, bonding layers, etc.).

In the illustrated example of FIG. 3, the first layer 304 is proximate to the dies 106, 108 and the second layer 306 is proximate to the substrate102 (e.g., the first layer 304 is closer to the dies 106, 108 than the second layer 306 is, the second layer 306 is closer to the substrate102 than the first layer 304 is, the first layer 304 is distal to the substrate102, the second layer 306 is distal to the dies 106, 108, etc.). That is, based on the orientation of the example second IC package 300 in FIG. 3, the first layer 304 is above the second layer 306 (e.g., the second layer 306 is below the first layer 304, etc.) and the third layer 308 is between the first layer 304 and the second layer 306. In the illustrated example of FIG. 3, a top surface of the first layer 304 abuts (e.g., directly contacts, etc.) the first build-up region 203A, a bottom surface of the second layer 306 abuts (e.g., directly contacts, etc.) the second build-up region 203B.

In the illustrated example of FIG. 3, each of the layers 304, 306, 308 has different coefficients of thermal expansion. For example, the first layer 304 can have a coefficient of thermal expansion that is less than the coefficient of thermal expansion of the third layer 308, and the third layer 308 can have a coefficient of thermal expansion that is less than the coefficient of thermal expansion of the second layer 306. In some such examples, the first layer 304 can have a glass composition with a coefficient of thermal expansion approximately equal to the coefficient of thermal expansion of the dies 106, 108 (e.g., the coefficient of thermal expansion of silicon, etc.), the second layer 306 can have a glass composition with a coefficient of thermal expansion approximately equal to the coefficient of thermal expansion of the substrate 102 or a component of the substrate 102 (e.g., the coefficient of thermal expansion of copper and/or laminate epoxy, etc.), and the third layer 308 can have a glass composition with a coefficient of thermal expansion between the coefficient of thermal expansion of the first layer 304 and the coefficient of thermal expansion of the second layer 306 (e.g., an average of the CTEs of the layers 304, 306, etc.). In some such examples, the third layer 308 can have a CTE of 10E-6 Kelvin⁻¹. That is, the second glass core 302 includes a medium CTE layer (e.g., the third layer 308, etc.) positioned between a high CTE layer (e.g., the second layer 306, etc.) and a low CTE layer (e.g., the first layer 304, etc.) (e.g., a low-medium-high CTE pattern, etc.). In other examples, the layers 304, 306, 308 can have any other suitable coefficients of thermal expansion. For example, the first layer 304 can have a coefficient of thermal expansion equal to the coefficient of thermal expansion of the second layer 306.

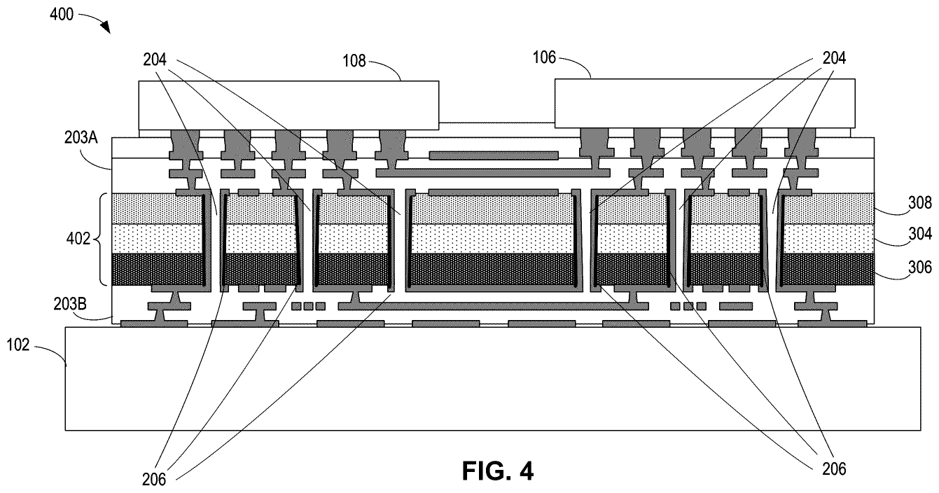

FIG. 4 is a cross-sectional side view of an example third IC package 400 that can implement the IC package 100 of FIG. 1. In the illustrated example of FIG. 4, the third IC package 400 includes an example third glass core 402. In the illustrated example of FIG. 4, the third IC package 400 includes the dies 106, 108 of FIG. 1 and is coupled to the substrate 102 of FIG. 1. In the illustrated example of FIG. 4, the third IC package 400 includes the build-up regions 203A, 203B of FIG. 2, the TGVs 204 of FIG. 2, and the liners 206 of FIG. 2. In the illustrated example of FIG. 4, the third glass core 402 includes the first layer 304 of FIG. 3, the second layer 306 of FIG. 3, and the third layer 308 of FIG. 3. In the illustrated example of FIG. 4, the third glass core 402 is similar to the second glass core 302 except that the positions of the first layer 304 and the third layer 308 have been reversed. That is, the glass core 402 includes a low CTE layer (e.g., the first layer 304, etc.) positioned between a high CTE layer (e.g., the third layer 308, etc.) and a medium CTE layer (e.g., the second layer 306, etc.) (e.g., a medium-low-high CTE pattern, etc.).

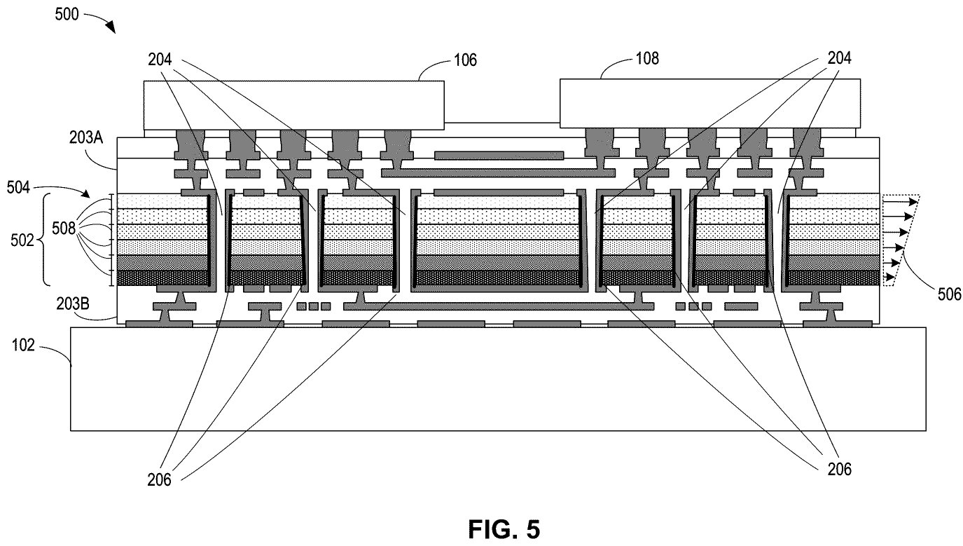

FIG. 5 is a cross-sectional side view of an example fourth IC package 500 that can implement the IC package 100 of FIG. 1. In the illustrated example of FIG. 5, the fourth IC package 500 includes an example fourth glass core 502. In the illustrated example of FIG. 5, the fourth IC package 500 includes the dies 106, 108 of FIG. 1 and is coupled to the substrate 102 of FIG. 1. In the illustrated example of FIG. 5, the fourth IC package 500 includes the build-up regions 203A, 203B of FIG. 2, the TGVs 204 of FIG. 2, and the liners 206 of FIG. 2. In the illustrated example of FIG. 5, the fourth glass core 502 includes an example plurality of layers 504 (also referred to herein as a plurality of regions) defining an example coefficient of thermal expansion (CTE) gradient 506.

In the illustrated example of FIG. 5, the plurality of layers 504 includes 6 layers. In other examples, the plurality of layers 504 can include a different number of layers (e.g., 10 layers, 50 layers, 100 layers, 500 layers, one thousand layers, etc.). In the illustrated example of FIG. 5, each of the plurality of layers 504 has an example thickness 508. That is, in the illustrated example of FIG. 5, each of the plurality of layers 504 has an equal thickness (e.g., the thickness 508, etc.). In some examples, the thickness 508 of each of the plurality of layers 504 is based on the spin-on thickness capability of the material of the plurality of layers 504 (e.g., the minimum possible spin-on coating thickness of the glass of which the plurality of layers 504 is composed of, 2 micrometers, etc.). In other examples, the thickness 508 can have any other suitable value. In other examples, some or all of the plurality of layers 504 can have thickness(es) different than the thickness 508. For example, the layers of the plurality of layers 504 adjacent to the build-up regions 203A, 203B (e.g., the layers of the plurality of layers 504 proximate to the dies 106, 108 and the substrate 102, etc.) can have thicknesses greater than or less than the thickness 508.

In the illustrated example of FIG. 5, the plurality of layers 504 define the example CTE gradient 506. In the illustrated example of FIG. 5, the CTE of each of the plurality of layers 504 is represented by an arrow that is laterally aligned with the corresponding one of the plurality of layers 504. In the illustrated example of FIG. 5, the length of each of the arrows is directly proportional to the magnitude of the CTE of the corresponding one of the plurality of layers 504. The CTE gradient 506 corresponds to a line fit to the ends of arrows corresponding to the CTE of the plurality of layers 504. In the illustrated example of FIG. 5, the CTE gradient 506 linearly increases from the bottom of the glass core 502 to the top of the glass core 502 (e.g., the CTE gradient 506 is linearly monotonic, etc.). In some such examples, the plurality of layers 504 defines the CTE gradient 506, which transitions between the CTE of a layer of the plurality of layers 504 adjacent to (proximate to, closest to) the dies 106, 108 and the CTE of a layer of the plurality of layers 504 adjacent to (proximate to, closest to) the substrate 102. In other examples, the CTE gradient 506 linearly decreases (e.g., the CTE gradient 506 is linearly monotonic, etc.) from the bottom of the glass core 502 (e.g., closest to the substrate 102) to the top of the glass core 502 (e.g., closest to the dies 106, 108). In other examples, the CTE gradient 506 is non-linearly monotonic (e.g., a monotonic polynomial function, a monotonic trigonometric function, a monotonic logarithmic, a line defined by multiple functions, etc.). In other examples, the CTE gradient 506 is non-monotonic (e.g., a binominal function, a cubic function, etc.) and includes local extrema in the middle of the glass core 502.

The glass cores 202, 302, 402, 502 of FIGS. 2-5 include a plurality of glass layers with different coefficients of thermal expansion. The glass cores 202, 302, 402, 502 of FIGS. 2-5 are integral (e.g., unibody, one-body, continuous, monolithic, etc.). That is, the different layers of the glass cores 202, 302, 402, 502 form covalent bonds with adjacent layers that are similar to the internal bonds of the layers. In some examples, the variable coefficient of thermal expansions of the glass cores 202, 302, 402, 502 of FIGS. 2-5 mitigates the potential damage to the glass cores 202, 302, 402, 502 of FIGS. 2-5 from seware, cracking, and other potential damage associated with thermal expansion. While 4 glass cores are described with reference to FIGS. 2-5 (e.g., the glass cores 202, 302, 402, 502, etc.), the examples disclosed herein are not limited thereto. For example, other glass cores implemented in accordance with teachings of the disclosure can include any suitable number of layers (e.g., four layers, five layers, ten layers, etc.). It should be appreciated that the dies 106, 108 of the IC packages of FIGS. 2-5 can be mounted on the first build-up region 203A via one or more interconnects (e.g., bumps, microbumps, pillars, etc.), which are not illustrated in the interest of visual clarity.

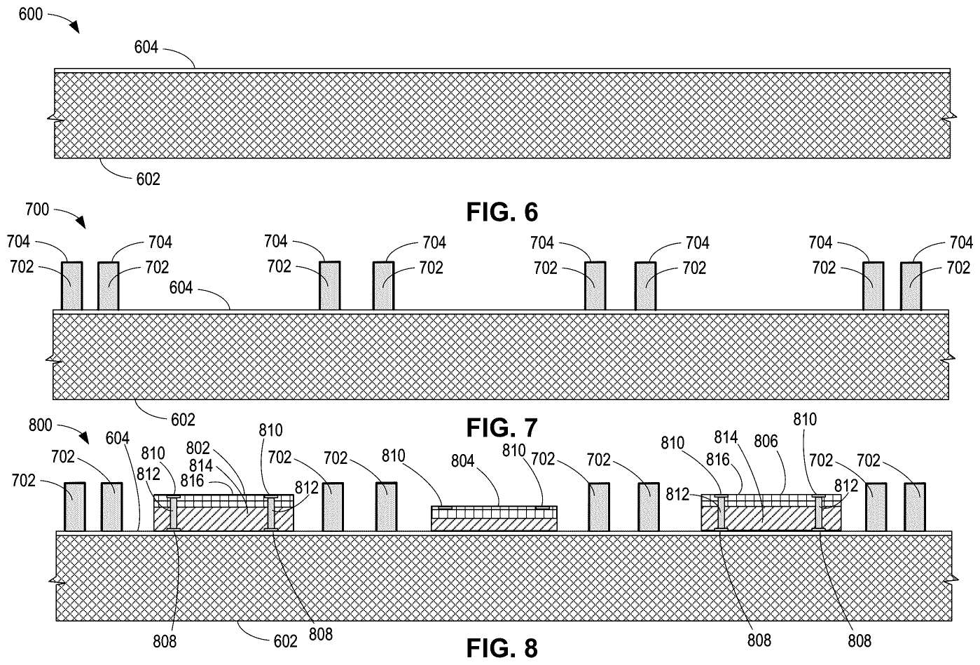

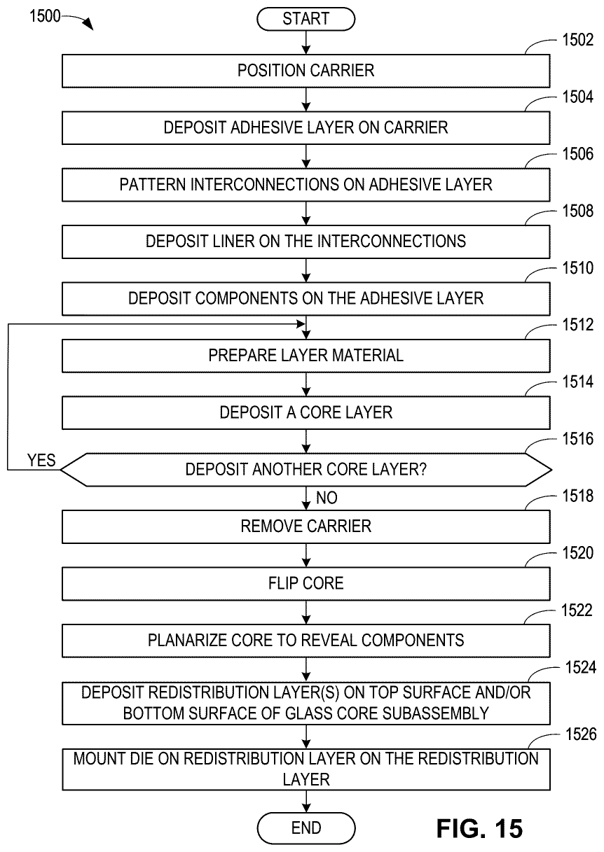

FIGS. 6-14 depict a plurality of intermediate stages in an example process to manufacture an example glass core 902 (FIG. 9). The glass core 902 of FIG. 9 can implement the first glass core 202 of FIG. 2, the second glass core 302 of FIG. 3, the third glass core 402 of FIG. 4, and/or the fourth glass core 502 of FIG. 5 based on the number and ordering of the layers of the glass core 902. It should be appreciated that other processes and/or intermediate stages can be used to manufacture the glass core 902 of FIG. 9. Example operations to manufacture the glass core 902 of FIG. 9 via the intermediate stages of FIGS. 6-14 are described below in conjunction with FIG. 15.

FIG. 6 is a cross-sectional schematic view of an example first intermediate stage 600 of the assembly/manufacturing of the glass core 902 of FIG. 9. During the first intermediate stage 600, an example carrier 602 is provided. For example, a carrier 602 can be positioned onto and/or within a die fabrication system and/or wafer fabrication system. The carrier 602 is a rigid component that supports the dies and/or other components of the glass core 902 to be manufactured via the intermediate stages of FIGS. 6-11. In some examples, the carrier 602 includes (e.g., is composed of, etc.) glass. Additionally or alternatively, the carrier 602 can include (e.g., is composed of, etc.) any rigid suitable material (e.g., epoxy-based prepreg, glass, silicon, germanium, selenium, tellurium, etc.). In the illustrated example, an example adhesive layer 604 is deposited on the carrier 602. In some examples, the adhesive layer 604 can be deposited as a thin film via thin film deposition. In other examples, the adhesive layer 604 is deposited via another process (e.g., a vapor deposition process, lamination, spin-coating, etc.). In some examples, the adhesive layer 604 includes (e.g., is composed of, etc.) an adhesive polymer.

FIG. 7 is a cross-sectional schematic view of an example second intermediate stage 700 of the assembly/manufacturing of the glass core 902 of FIG. 9. In some examples, the second intermediate stage 700 can occur after the first intermediate stage 600 of FIG. 6. During the second intermediate stage 700, the TGVs 702 are deposited on the adhesive layer 604 and the carrier 602. The TGVs 702 are similar to the TGVs 204 of FIG. 2, except as noted otherwise. In some examples, the TGVs 702 are formed via lithography and electroplating (e.g., bottom-up plating, etc.). In other examples, the TGVs 702 are deposited via another process (e.g., vapor deposition, pick and place, etc.). The TGVs 702 include (e.g., are composed of, etc.) a conductive material (e.g., copper, silver, aluminum, etc.). While the illustrated example of FIG. 9 depicts eight interconnects (e.g., the TGVs 702, etc.), in other examples, a different quantity (e.g., one interconnect, two interconnects, ten interconnects, etc.) of TGVs 702 can be formed on the carrier 602 during the intermediate stage 700.

In the illustrated example of FIG. 7, the TGVs 702 include example liners 704 deposited thereon. In some examples, the liners 704 protect (e.g., shield, etc.) the interconnects during the manufacturing of the glass core 902 (e.g., the intermediate stages 800, 900, 1000, 1100 of FIGS. 11, etc.) and/or thermal stresses during operation of an integrated circuit package including the glass core 902. In some examples, the tops of the TGVs 702 are patterned to remove portions of the liners 704 positioned thereon to enable electric signals to pass therethrough. The liners 704 are similar to the liners 206 of FIG. 2, except as noted otherwise. In some examples, the liners 704 can be deposited via lithography, thin-film deposition, vapor deposition, lamination, and/or a combination, etc. In some examples, the liners 704 are absent.

FIG. 8 is a cross-sectional schematic view of an example third intermediate stage 800 of the assembly/manufacturing of the glass core 902 of FIG. 9. In some examples, the third intermediate stage 800 can occur after the second intermediate stage 700 of FIG. 7. During the third intermediate stage 800, an example first component 802, an example second component 804, and an example third component 806 are deposited on the adhesive layer 604 and the carrier 602 between ones of the TGVs 702. In some examples, one or more of the components 802, 804, and 806 can be implemented by active electronic components (e.g., logic or memory ICs), or inactive components (e.g., capacitors, inductors or resistors). For example, components 802, 804, and 806 can be implemented by one or more embedded discrete passive components (inductors, resistors, capacitors), logic ICs (dies/tiles/chiplets) with or without Through Silicon Vias (TSVs), discrete memory ICs (High Bandwidth Memory (HBM), Dynamic Random Access Memory (DRAM), etc.), voltage regulation ICs (VR controllers), etc.

In the illustrated example of FIG. 8, the first component 802 and the second component 806 include example first pads 808 that abut the carrier 602. In the illustrated example of FIG. 8, the components 802, 804, 806 include second pads 810 that are distal to the carrier 602. In the illustrated example of FIG. 8, the first component 802 and the second component 806 include interconnections 812 (e.g., through silicon vias (TSVs), etc.) that extend between the first pads 808 and the second pads 810. The interconnections 812 enable electrical signals and/or power to be transmitted through the components 802, 806. In some examples, some or all of the pads 808, 810 and the interconnections 812 are absent. In the illustrated example of FIG. 8, the components 802, 804, 806 include example silicon layers 814 and example device layers 816 provided on the silicon layers 814. The device layers 816 can include one or more active circuit components (e.g., transistors, integrated circuits, diodes, etc.) and/or passive circuit components (e.g., capacitors, inductors, etc.) that are electrically coupled to the pads 808, 810 and/or the interconnections 812.

In some examples, some or all of the components 802, 804, 806 are fabricated separately and mechanically deposited on the adhesive layer 604 as integrated component(s). In some examples, the components 802, 804, 806 can be processed (e.g., via one or more semiconductor fabrication techniques, etc.) after deposition on the adhesive layer 604. Additionally or alternatively, some of all of the components 802, 804, 806 can be fabricated directly on the adhesive layer 604 (e.g., via lithography, plating, vapor deposition, etc.). In some examples, some or all of the components 802, 804, 806 are absent. In some such examples, the intermediate stage 800 is omitted.

FIG. 9 is a cross-sectional schematic view of an example fourth intermediate stage 900 of the assembly/manufacturing of the glass core 902. In some examples, the fourth intermediate stage 900 can occur after the third intermediate stage 800 of FIG. 8. During the fourth intermediate stage 900, the glass core 902 is deposited on the adhesive layer 604 and the carrier 602. In the illustrated example of FIG. 9, the glass core 902 includes an example first layer 904 (also referred to herein as a first region), an example second layer 906 (also referred to herein as a second region), and an example third layer 908 (also referred to herein as a third region).

The layers 904, 906, 908 can be deposited via spin-coating. For example, the material associated each of the layers 904, 906, 908 (e.g., a particular glass composition having a desired CTE, etc.) can be sequentially mixed, heated until having a sufficiently low viscosity suitable for spin-coating, and spin-coated onto the adhesive layer 604 and/or the previously deposited layer. In other examples, the layers 904, 906, 908 can be deposited via another deposition techniques, such as slit-coating and/or slot-die coating. In some examples, the material associated with the first layer 904 can be mixed to have a CTE approximately equal to silicon dies (e.g., approximately 3E-6 Kelvin⁻¹, etc.), heated until the material has a low viscosity (e.g., heated to 2000 degrees Celsius, etc.), and spin-coated onto the adhesive layer 604. In some such examples, the material associated with the second layer 906 can be mixed to have a CTE between the CTEs of the first layer 904 and the third layer 908 (e.g., approximately 10E-6 Kelvin⁻¹, etc.), heated until the material has a low viscosity (e.g., heated to 2000 degrees Celsius, etc.), and spin-coated onto the first layer 904. In some such examples, the material associated with the third layer 908 can be mixed to have a CTE approximately equal to a printed circuit board (e.g., approximately 20E-6 Kelvin⁻¹, approximately 15E-6 Kelvin⁻¹, etc.), heated until the material has a low viscosity (e.g., heated to 2000 degrees Celsius, etc.), and spin-coated onto the second layer 906. In some examples, as the glass core 902 cools, the layers 904, 906, 908 form covalent bonds therebetween (e.g., equivalent to the bonds between the molecules within each of the layers 904, 906, 908, which causes the glass core 902 to be a unibody core (e.g., the glass core 902 is integral, the glass core 902 is monolithic, the glass core 902 is continuous, etc.). In other examples, intermediate layers (e.g., adhesive layers, build-up layers, etc.) are deposited between the first layer 904 and the second layer 906 and/or the second layer 906 and the third layer 908.

In some examples, the thickness of each of the layers 904, 906, 908 can be controlled via the volume of material spin-coated onto to the adhesive layer 604 and/or the previously deposited layer (e.g., a greater volume of material spin-coated causes the layer to have a correspondingly greater thickness, etc.). It should be appreciated that in the illustrated examples of FIGS. 6-11, the layers 904, 906, 908 are deposited top to bottom because the glass core 902 is to be flipped during the intermediate stage 1100 of FIG. 11. In other examples, the layers 904, 906, 908 are deposited bottom to top (e.g., when the glass core 902 is not to be flipped, etc.). In the illustrated example of FIG. 9, the glass core 902 includes three layers (e.g., the layers 904, 906, 908, etc.). In other examples, the glass core 902 can include two layers (e.g., similar to the first glass core 202 of FIG. 2, etc.) and/or more than three layers (e.g., similar to the fourth glass core 502 of FIG. 5, etc.). In some examples, each of the layers of the glass core 902 can be sequentially mixed, heated, and spin-coated onto the adhesive layer 604 and/or the previously deposited layer.

FIG. 10 is a cross-sectional schematic view of an example fifth intermediate stage 1000 of the assembly/manufacturing of the glass core 902 of FIG. 9. In some examples, the fifth intermediate stage 1000 can occur after the fourth intermediate stage 900 of FIG. 10. During the fifth intermediate stage 1000, the carrier 602 and the adhesive layer 604 have been removed from the bottom of the glass core 902. For example, the carrier 602 and/or the adhesive layer 604 can be mechanically removed from the glass core 902. In other examples, the glass core 902 and/or the adhesive layer 604 is removed via planarization.

FIG. 11 is a cross-sectional schematic view of an example sixth intermediate stage 1100 of the assembly/manufacturing of the glass core 902 of FIG. 9. In some examples, the sixth intermediate stage 1100 can occur after the fifth intermediate stage 1000 of FIG. 10. During the sixth intermediate stage 1100, the glass core 902 is flipped. For example, the orientation of the glass core 902 can be moved such that example exposed surfaces 1102 of the components 802, 804, 806 are on the top of the glass core 902. In some examples, interconnects, pads, and/or contacts can be coupled to corresponding features of the exposed surfaces 1102 of the components 802, 804, 806. After the intermediate stage 1100, other components (e.g., build-up regions, dies, etc.) can be deposited and/or fabricated on the glass core 902 to fabricate an integrated circuit package.

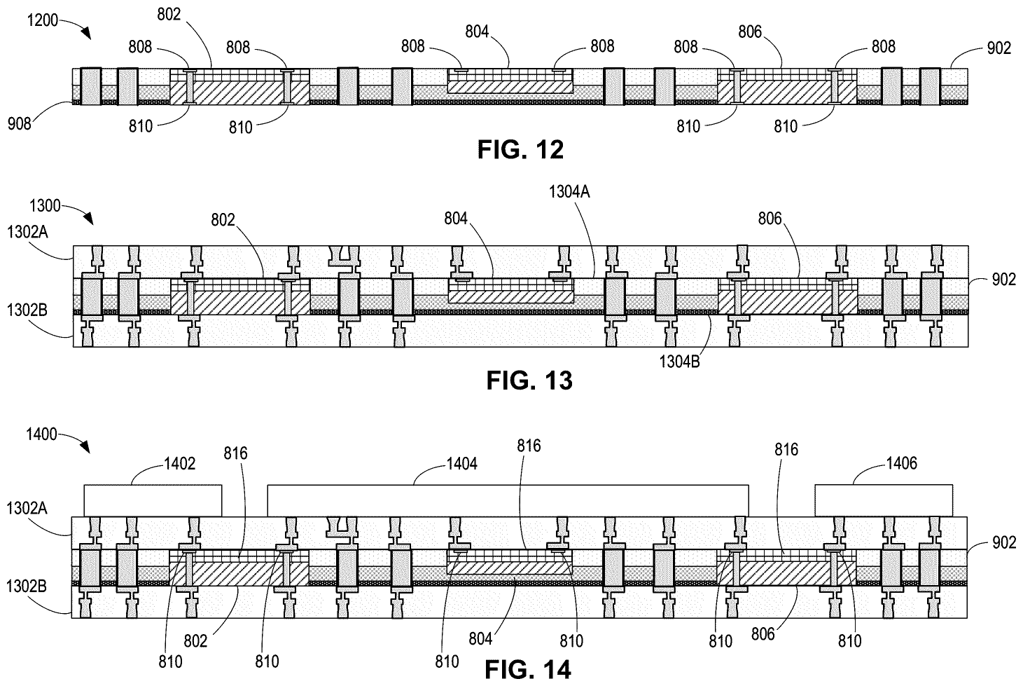

FIG. 12 is a cross-sectional schematic view of an example seventh intermediate stage 1200 of the assembly/manufacturing of the glass core 902 of FIG. 9. In some examples, the seventh intermediate stage 1200 can occur after the sixth intermediate stage 1100 of FIG. 11. During the seventh intermediate stage 1200, the third layer is thinned (e.g., planarized, polished, etc.) to reveal the second pads 810 of the components 802, 804, 806. For example, the third layer 906 can be thinned via chemical mechanical polishing, etching, and/or another suitable method. In some examples, the first layer 904 can be similarly thinned to reveal the first pads 808.

In the illustrated example of FIG. 12, the third layer 908 is depicted as having a smaller thickness than the layers 904, 906 after the thinning of the seventh intermediate stage 1200. In other examples, the third layer 908 can be deposited with a greater thickness during the intermediate stage 900 of FIG. 9, such that the third layer 908 has an equal thickness as the layers 904, 906 after the seventh intermediate stage 1200 of FIG. 12. In some such examples, the seventh intermediate stage 1200 of FIG. 12 is omitted (e.g., the components 802, 804, 806 have a thickness equal to the thickness of the core 902, the components 802, 804, 806 are absent, etc.).

FIG. 13 is a cross-sectional schematic view of an example eighth intermediate stage 1300 of the assembly/manufacturing of the glass core 902 of FIG. 9. In some examples, the eighth intermediate stage 1300 can occur after the seventh intermediate stage 1200 of FIG. 12. During the eighth intermediate stage 1300, an example first redistribution layer 1302A and an example second redistribution layer 1302B have been deposited on an example first surface 1304A of the glass core 902 and an example second surface 1304B of the glass core 902, respectively. The redistribution layers 1302A, 1302B include one or more conductive interconnections (e.g., vias, pads, bumps, etc.) disposed within a dielectric filler material (e.g., Ajinomoto build-up film (ABF), etc.). The conductive interconnections of the first redistribution layer 1302A transmit power and/or electrical signals between the glass core 902 (e.g., the components 802, 804, 806, the TGVs 702, etc.) and components mounted on the first redistribution layer 1302A. The conductive interconnections of the second redistribution layer 1302B transmit power and/or electrical signals between the glass core 902 (e.g., the components 802, 804, 806, the TGVs 702, etc.) and components below the glass core 902 (e.g., the substrate 102 of FIG. 1, etc.). In some examples, the interconnections of the redistribution layers 1302A, 1302B can redistribute (e.g., split, merge, redirect, etc.) the electrical connections transmitted therethrough.

FIG. 14 is a cross-sectional schematic view of an example ninth intermediate stage 1400 of the assembly/manufacturing of the glass core 902 of FIG. 9. In some examples, the ninth intermediate stage 1400 can occur after the eighth intermediate stage 1300 of FIG. 13. During the ninth intermediate stage 1400, an example first die 1402, an example second die 1404, and an example third die 1406 are mounted on first redistribution layer 1302A of FIG. 13. In some examples, the dies 1402, 1404, 1406 (e.g., chips, chiplets, etc.) can be mounted via a flip chip connection. In other examples, some or all of the dies 1402, 1404, 1406 are mounted via one or more pins, lands, and/or other connections. In some examples, the dies 1402, 1404, 1406 are mounted on the first redistribution layer 1302A via one or more interconnects (e.g., bumps, microbumps, pillars, etc.), which are not illustrated in the interest of visual clarity.

In the illustrated example of FIG. 14, the first component 802 is a bridge that electrically couples the first die 1402 and the second die 1404 (e.g., via electrical connections in the first redistribution layer 1302A, the first pads 808 and connections in the device layer 816 of the first component 802, etc.). In the illustrated example of FIG. 14, the second component 804 is electrically coupled to the second die 1404 (e.g., via electrical connections in the first redistribution layer 1302A and the first pads 808, etc.). In the illustrated example of FIG. 14, the third component 806 is a bridge that electrically couples the third die 1406 and the second die 1404 (e.g., via electrical connections in the first redistribution layer 1302A, the first pads 808, and connections in the device layer 816 of the third component 806, etc.). In other examples, the components 802, 804, 806 can be electrically coupled to the dies 1402, 1404, 1406 in any other suitable manner. The dies 1402, 1404, 1406 can be implemented by any suitable type of integrated circuit(s). For example, the first die 1402 and the third die 1406 can be implemented via a memory integrated circuit (e.g., a High Bandwidth Memory (HBM), etc.) and the second die 1404 can be implemented by a logic die. FIG. 15 is a block diagram of example operations 1500 for manufacturing a glass core implemented in accordance with teachings of this disclosure. For example, the example operations 1500 can be used to manufacture the glass core 130 of FIG. 1, the first glass core 202 of FIG. 2, the second glass core 302 of FIG. 3, the third glass core 402 of FIG. 4, the fourth glass core 502 of FIG. 5, and/or the glass core 902 of FIGS. 9-11. The operations 1500 begin at block 1502, at which the carrier 602 of FIG. 6 is positioned. For example, the carrier 602 can be placed in a fabrication environment (e.g., in a die fabrication system, in a wafer fabrication system, etc.). At block 1504, the adhesive layer 604 of FIG. 6 is deposited on the carrier. For example, the adhesive layer 604 can be deposited via thin film deposition (TFD), a vapor deposition process (e.g., ALD, PVD, CVD, etc.), lamination, etc. The point of fabrication after completion of block 1504 corresponds to the structure of the first intermediate stage 600 of FIG. 6.

At block 1506, the TGVs 702 are patterned on the adhesive layer 604. For example, the TGVs 702 can be formed via lithography and electroplating (e.g., bottom-up plating, etc.). In other examples, the TGVs 702 are deposited via another process (e.g., vapor deposition, pick and place, etc.). At block 1508, the liners 704 of FIG. 7 are deposited on the TGVs 702. For example, the liners 704 can be deposited via lithography, thin-film deposition, vapor deposition, lamination, and/or a combination, etc. In some examples, the tops of the TGVs 702 are processed to remove portions of the liners 704 positioned thereon to enable electric signals to pass therethrough (e.g., via grinding, via polishing, via planarization, etc.). The point of fabrication after completion of block 1508 corresponds to the structure of the second intermediate stage 700 of FIG. 7.

At block 1510, the components 802, 804, 806 are deposited on the adhesive layer 604. For example, the components 802, 804, 806 are fabricated separately and mechanically deposited on the adhesive layer 604 as integrated component(s). In some examples, the components 802, 804, 806 can be processed (e.g., via one or more semiconductor fabrication techniques, etc.) after deposition on the adhesive layer 604. Additionally or alternatively, some of all of the components 802, 804, 806 can be fabricated directly on the adhesive layer 604 (e.g., via lithography, plating, vapor deposition, etc.). In some examples, some or all of the components 802, 804, 806 are absent. The point of fabrication after completion of block 1510 corresponds to the structure of the third intermediate stage 800 of FIG. 8.

At block 1512, the material of the core layer to be deposited is prepared. For example, a particular composition of glass can be mixed. In some such examples, the coefficients of thermal expansion of each of the layers of the glass core 130 can be tailored by varying the relative proportions of Al2O3, B2O3, Li₂O, Na2O, K2O, Sb2O3, and/or other additives in each of the layers and/or via processing variations (e.g., lamination cladding, thermal treatment, etc.).

At block 1514, a core layer is deposited. For example, one of the layers 904, 906, 908 can be deposited on the adhesive layer 604 and/or a previously deposited layer via spin-coating. In some such examples, the material prepared during the execution of block 1512 can be heated until the material flows and spin-coated onto the adhesive layer 604 and/or a previously deposited layer. In other examples, the core layer can be deposited in another suitable manner (e.g., slit coating, etc.). For example, the core layer can be manufactured separately and deposited on the adhesive layer 604 and/or a previously deposited layer.

At block 1516, it is determined if another layer is to be deposited. For example, another layer can be deposited until the glass core 902 has a predetermined thickness and/or until a particular number of layers have been deposited. For example, the execution of blocks 1512 and 1514 can be repeated until three layers have been deposited. If another core layer is to be deposited, the operations 1500 return to block 1512. If another core layer is not to be deposited, the operations advance to block 1518. The point of fabrication after a negative completion of block 1510 corresponds to the structure of the fourth intermediate stage 900 of FIG. 9.

At block 1518, the carrier 602 is removed from the glass core 902. For example, the carrier 602 can be mechanically removed from the glass core 902 and/or the glass core 902 can be mechanically removed from the carrier 602. Additionally or alternatively, the carrier 602 is removed via planarization. In some examples, the adhesive layer 604 can be removed with the carrier 602. In other examples, the adhesive layer 604 is not removed from the glass core 902. The point of fabrication after completion of block 1518 corresponds to the structure of the fifth intermediate stage 1000 of FIG. 10. At block 1520, the glass core 902 is flipped (e.g., rotated 180 degrees, etc.). For example, the glass core 902 can be flipped mechanically. The point of fabrication after completion of block 1520 corresponds to the structure of the sixth intermediate stage 1100 of FIG. 11.

At block 1522, the glass core 902 is planarized to reveal the components 802, 804, 806. For example, the outermost layers of the glass core 902 (e.g., the first layer 904, the third layer 908, etc.) until the first pads 808 and/or the second pads 810, respectively. In some examples, the glass core 902 can be planarized via chemical mechanical polishing and/or etching. The point of fabrication after completion of block 1522 corresponds to the structure of the seventh intermediate stage 1200 of FIG. 12. At block 1524, the redistribution layer(s) 1302A, 1302B are deposited on the top surface 1304A and/or the bottom surface 1304B of the glass core 902. For example, the materials for additional redistribution layer(s) (e.g., the dielectric layers, interconnections, etc.) can be deposited on the top surface 1304A of the glass core 902 and the bottom surface 1304B of the glass core 902. The point of fabrication after completion of block 1524 corresponds to the structure of the eighth intermediate stage 1300 of FIG. 13.

At block 1526, the dies 1402, 1404, 1406 are mounted on the first redistribution layer 1302A. For example, the dies 1402, 1404, 1406 can be mounted on the first redistribution layer 1302A via a flip chip connection. In other examples, the dies 1402, 1404, 1406 are mounted on the first redistribution layer 1302A via any other suitable method. The point of fabrication after completion of block 1526 corresponds to the structure of the nineth intermediate stage 1400 of FIG. 14. Thereafter, the operations 1500 end.

Although the example operations 1500 are described with reference to the flowchart illustrated in FIG. 15, many other methods of assembling/manufacturing the glass core 130 of FIG. 1, the first glass core 202 of FIG. 2, the second glass core 302 of FIG. 3, the third glass core 402 of FIG. 4, the fourth glass core 502 of FIG. 5, and/or the glass core 902 of FIGS. 9-11 may alternatively be used. Additionally or alternatively, the order of execution of the blocks of the operations 1500 may be changed, and/or some of the blocks described may be changed, eliminated, or combined.

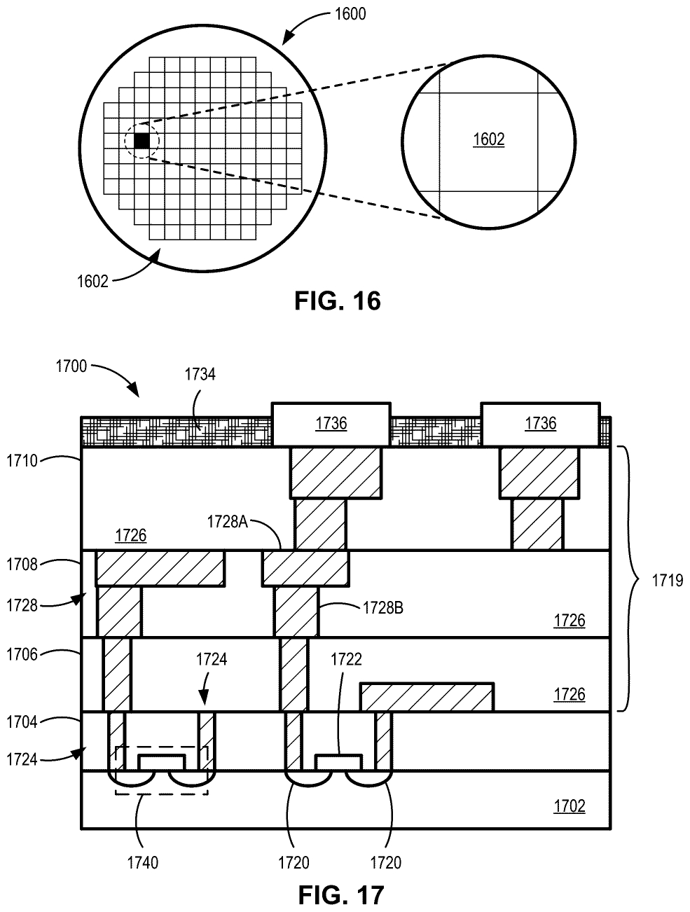

FIG. 16 is a top view of an example wafer 1600 and dies 1602 that may be included in the IC package 100 (e.g., as any suitable ones of the dies 106, 108, etc.). The wafer 1600 may be composed of semiconductor material and may include one or more dies 1602 having circuitry. Some or all of the dies 1602 may be a repeating unit of a semiconductor product. After the fabrication of the semiconductor product is complete, the wafer 1600 may undergo a singulation process in which the dies 1602 are separated from one another to provide discrete “chips.” One or more of the dies 1602 may include one or more transistors (e.g., some of the transistors 1740 of FIG. 17, discussed below), supporting circuitry to route electrical signals to the transistors, passive components (e.g., traces, resistors, capacitors, inductors, and/or other circuitry), and/or any other components. In some examples, the dies 1602 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die (e.g., a die of the dies 1602 of FIG. 16, etc.). For example, a memory array formed by multiple memory circuits may be formed on a same die (e.g., one of the dies 1602 of FIG. 16, etc.) as programmable circuitry or other logic circuitry. Such memory may store information for use by the programmable circuitry. The example IC package 100 disclosed herein may be manufactured using a die-to-wafer assembly technique in which the dies 106, 108, etc. are attached to a wafer 1600 that includes others of the dies 106, 108, and the wafer 1600 is subsequently singulated.

FIG. 17 is a cross-sectional side view of an example IC device 1700 that may be included in the example IC package 100 (e.g., in any one of the dies 106, 108, etc.). One or more of the IC devices 1700 may be included in one or more dies 1602 (FIG. 16). The IC device 1700 may be formed on an example die substrate 1702 (e.g., the wafer 1600 of FIG. 16) and may be included in a die (e.g., a die of the dies 1602 of FIG. 16). The die substrate 1702 may be a semiconductor substrate composed of semiconductor material systems including, for example, n-type or p-type materials systems (or a combination of both). The die substrate 1702 may include, for example, a crystalline substrate formed using a bulk silicon or a silicon-on-insulator (SOI) substructure. In some examples, the die substrate 1702 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1702. Although a few examples of materials from which the die substrate 1702 may be formed are described here, any material that may serve as a foundation for an IC device 1700 may be used. The die substrate 1702 may be part of a singulated die (e.g., the dies 1602 of FIG. 16) or a wafer (e.g., the wafer 1600 of FIG. 16).

The IC device 1700 may include one or more example device layers 1704 on or above the die substrate 1702. The device layer 1704 may include features of one or more example transistors 1740 (e.g., metal oxide semiconductor field-effect transistors (MOSFETs)) formed on the die substrate 1702. The device layer 1704 may include, for example, one or more example source and/or drain (S/D) regions 1720, an example gate 1722 to control current flow between the S/D regions 1720, and one or more example S/D contacts 1724 to route electrical signals to/from the S/D regions 1720. The transistors 1740 may include additional features not depicted for the sake of clarity such as, for example, device isolation regions, gate contacts, and the like. The transistors 1740 are not limited to the type and configuration depicted in FIG. 17 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1740 may include an example gate 1722 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1740 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as, for example, a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1740 along the source-channel-drain direction, the gate electrode may include a U-shaped structure that includes a bottom portion substantially parallel to the surface of the die substrate 1702 and two sidewall portions that are substantially perpendicular to the top surface of the die substrate 1702. In other examples, at least one of the metal layers that form the gate electrode may be a planar layer that is substantially parallel to the top surface of the die substrate 1702 and does not include sidewall portions substantially perpendicular to the top surface of the die substrate 1702. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1720 may be formed within the die substrate 1702 adjacent to the gate 1722 of respective ones of the transistors 1740. The S/D regions 1720 may be formed using an implantation/diffusion process or an etching/deposition process, for example. In the former process, dopants such as boron, aluminum, antimony, phosphorous, or arsenic may be ion-implanted into the die substrate 1702 to form the S/D regions 1720. An annealing process that activates the dopants and causes the dopants to diffuse farther into the die substrate 1702 may follow the ion-implantation process. In the latter process, the die substrate 1702 may first be etched to form recesses at the locations of the S/D regions 1720. An epitaxial deposition process may then be carried out to fill the recesses with material that is used to fabricate the S/D regions 1720. In some implementations, the S/D regions 1720 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1720 may be formed using one or more alternate semiconductor materials such as germanium or a group III-V material or alloy. In further examples, one or more layers of metal and/or metal alloys may be used to form the S/D regions 1720.

Electrical signals, such as power and/or input/output (I/O) signals, may be routed to and/or from the devices (e.g., transistors 1740) of the device layer 1704 through one or more example interconnect layers on the device layer 1704 (illustrated in FIG. 17 as interconnect layers 1706-1710). For example, electrically conductive features of the device layer 1704 (e.g., the gate 1722 and the S/D contacts 1724) may be electrically coupled with example interconnect structures 1728 of the interconnect layers 1706-1710. The one or more interconnect layers 1706-1710 may form an example metallization stack (also referred to as an “ILD stack”) 1719 of the IC device 1700.

The interconnect structures 1728 may be arranged within the interconnect layers 1706-1710 to route electrical signals according to a wide variety of designs (in particular, the arrangement is not limited to the particular configuration of interconnect structures 1728 depicted in FIG. 17). Although a particular number of interconnect layers 1706-1710 is depicted in FIG. 17, examples of the present disclosure include IC devices having more or fewer interconnect layers than depicted.

In some examples, the interconnect structures 1728 may include example lines 1728A and/or example vias 1728B filled with an electrically conductive material such as a metal. The lines 1728A may be arranged to route electrical signals in a direction of a plane that is substantially parallel with a surface of the die substrate 1702 upon which the device layer 1704 is formed. For example, the lines 1728A may route electrical signals in a direction in and out of the page from the perspective of FIG. 17. The vias 1728B may be arranged to route electrical signals in a direction of a plane that is substantially perpendicular to the surface of the die substrate 1702 upon which the device layer 1704 is formed. In some examples, the vias 1728B may electrically couple lines 1728A of different interconnect layers 1706-1710 together.

The interconnect layers 1706-1710 may include an example dielectric material 1726 between the interconnect structures 1728, as shown in FIG. 17. In some examples, the dielectric material 1726 between the interconnect structures 1728 in different ones of the interconnect layers 1706-1710 may have different compositions. In other examples, the composition of the dielectric material 1726 between different interconnect layers 1706-1710 may be the same.

A first interconnect layer 1706 (referred to as Metal 1 or “M1”) may be formed directly on the device layer 1704. In some examples, the first interconnect layer 1706 may include lines 1728A and/or vias 1728B, as shown. The lines 1728A of the first interconnect layer 1706 may be coupled with contacts (e.g., the S/D contacts 1724) of the device layer 1704.

A second interconnect layer 1708 (referred to as Metal 2 or “M2”) may be formed directly on the first interconnect layer 1706. In some examples, the second interconnect layer 1708 may include vias 1728B to couple the lines 1728A of the second interconnect layer 1708 with the lines 1728A of the first interconnect layer 1706. Although the lines 1728A and the vias 1728B are structurally delineated with a line within each interconnect layer (e.g., within the second interconnect layer 1708) for the sake of clarity, the lines 1728A and the vias 1728B may be structurally and/or materially contiguous (e.g., simultaneously filled during a dual-damascene process) in some examples.

A third interconnect layer 1710 (referred to as Metal 3 or “M3”) (and additional interconnect layers, as desired) may be formed in succession on the second interconnect layer 1708 according to similar techniques and configurations described in connection with the second interconnect layer 1708 and/or the first interconnect layer 1706. In some examples, the interconnect layers that are “higher up” in the metallization stack 1719 in the IC device 1700 (i.e., further away from the device layer 1704) may be thicker.

The IC device 1700 may include an example solder resist material 1734 (e.g., polyimide or similar material) and one or more example conductive contacts 1736 formed on the interconnect layers 1706-1710. In FIG. 17, the conductive contacts 1736 are illustrated as taking the form of bond pads. The conductive contacts 1736 may be electrically coupled with the interconnect structures 1728 and configured to route the electrical signals of the transistor(s) 1740 to other external devices. For example, solder bonds may be formed on the one or more conductive contacts 1736 to mechanically and/or electrically couple a chip including the IC device 1700 with another component (e.g., a circuit board). The IC device 1700 may include additional or alternate structures to route the electrical signals from the interconnect layers 1706-1710; for example, the conductive contacts 1736 may include other analogous features (e.g., posts) that route the electrical signals to external components.

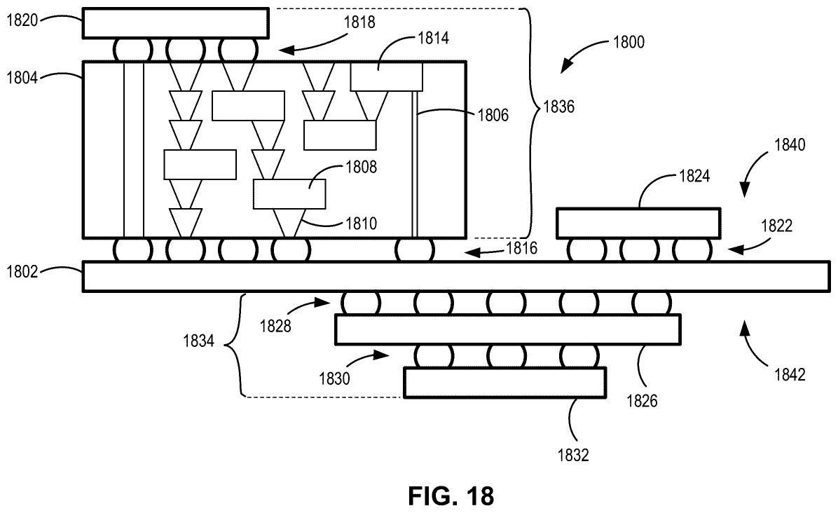

FIG. 18 is a cross-sectional side view of an example IC device assembly 1800 that may include the IC package 100 disclosed herein. In some examples, the IC device assembly corresponds to the IC package 100. The IC device assembly 1800 includes a number of components on an example circuit board 1802 (which may be, for example, a motherboard). The IC device assembly 1800 includes components on an example first face 1840 of the circuit board 1802 and an example opposing second face 1842 of the circuit board 1802. Any of the IC packages discussed herein with reference to the IC device assembly 1800 may take the form of the example IC package 100.

In some examples, the circuit board 1802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1802. In other examples, the circuit board 1802 may be a non-PCB substrate. In some examples, the circuit board 1802 may be, for example, the substrate 102 of FIG. 1.

The IC device assembly 1800 illustrated in FIG. 18 includes an example package-on-interposer structure 1836 coupled to the first face 1840 of the circuit board 1802 by example coupling components 1816. The coupling components 1816 may electrically and mechanically couple the package-on-interposer structure 1836 to the circuit board 1802, and may include solder balls (as shown in FIG. 18), male and female portions of a socket, an adhesive, an underfill material, and/or any other suitable electrical, chemical, and/or mechanical coupling structure.

The package-on-interposer structure 1836 may include an example IC package 1820 coupled to an example interposer 1804 by example coupling components 1818. The coupling components 1818 may take any suitable form for the application, such as the forms discussed above with reference to the coupling components 1816. Although a single IC package 1820 is shown in FIG. 18, multiple IC packages may be coupled to the interposer 1804. Additionally or alternatively, in some examples, additional interposers may be coupled to the interposer 1804. The interposer 1804 may provide an intervening substrate used to bridge the circuit board 1802 and the IC package 1820. The IC package 1820 may be or include, for example, a die (e.g., a die of the dies 1602 of the dies of FIG. 16), an IC device (e.g., the IC device 1700 of FIG. 17), and/or any other suitable component(s). Generally, the interposer 1804 may spread a connection to a wider pitch or reroute a connection to a different connection. For example, the interposer 1804 may couple the IC package 1820 (e.g., a die) to a set of BGA conductive contacts of the coupling components 1816 for coupling to the circuit board 1802. In the example illustrated in FIG. 18, the IC package 1820 and the circuit board 1802 are attached to opposing sides of the interposer 1804. In other examples, the IC package 1820 and the circuit board 1802 may be attached to a same side of the interposer 1804. In some examples, three or more components may be interconnected by way of the interposer 1804.

In some examples, the interposer 1804 may be formed as a PCB, including multiple metal layers separated from one another by layers of dielectric material and interconnected by electrically conductive vias. In some examples, the interposer 1804 may be formed of an epoxy resin, a fiberglass-reinforced epoxy resin, an epoxy resin with inorganic fillers, a ceramic material, or a polymer material such as polyimide. In some examples, the interposer 1804 may be formed of alternate rigid or flexible materials that may include the same materials described above for use in a semiconductor substrate, such as silicon, germanium, and other group III-V and group IV materials. The interposer 1804 may include example metal interconnects 1808 and example vias 1810, including but not limited to example through-silicon vias (TSVs) 1806. The interposer 1804 may further include example embedded devices 1814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1804. The package-on-interposer structure 1836 may take the form of any of the package-on-interposer structures known in the art.

The IC device assembly 1800 may include an example IC package 1824 coupled to the first face 1840 of the circuit board 1802 by example coupling components 1822. The coupling components 1822 may take the form of any of the examples discussed above with reference to the coupling components 1816, and the IC package 1824 may take the form of any of the examples discussed above with reference to the IC package 1820.

The IC device assembly 1800 illustrated in FIG. 18 includes an example package-on-package structure 1834 coupled to the second face 1842 of the circuit board 1802 by coupling components 1828. The package-on-package structure 1834 may include a first example IC package 1826 and a second example IC package 1832 coupled together by example coupling components 1830 such that the first IC package 1826 is between the circuit board 1802 and the second IC package 1832. The coupling components 1828, 1830 may take the form of any of the examples of the coupling components 1816 discussed above, and the IC packages 1826, 1832 may take the form of any of the examples of the IC package 1820 discussed above.

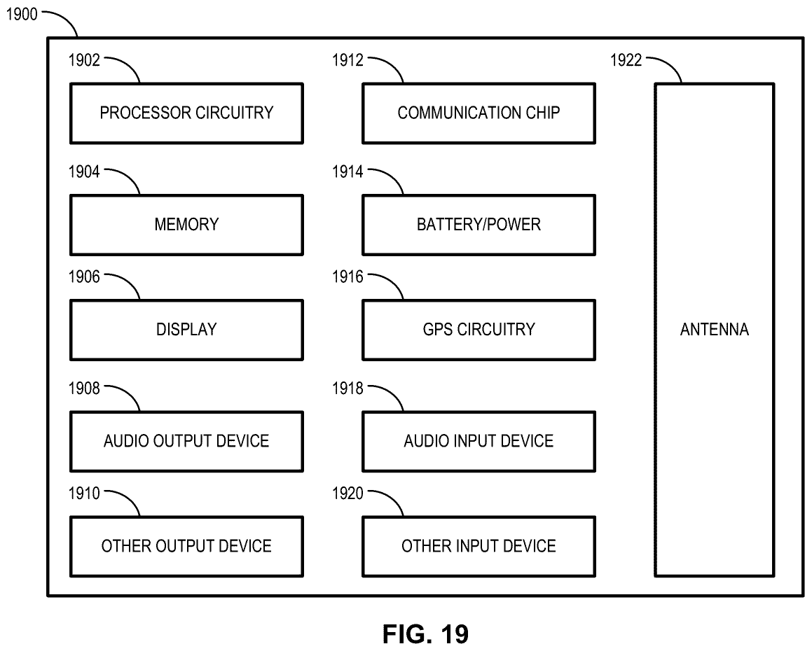

FIG. 19 is a block diagram of an example electrical device 1900 that may include one or more of the example IC package 100. For example, any suitable ones of the components of the electrical device 1900 may include one or more of the device assemblies 1800, IC devices 1700, or dies 1602 disclosed herein, and may be arranged in the example IC package 100. A number of components are illustrated in FIG. 19 as included in the electrical device 1900, but any one or more of these components may be omitted or duplicated, as suitable for the application. In some examples, some or all of the components included in the electrical device 1900 may be attached to one or more motherboards. In some examples, some or all of these components are fabricated onto a single system-on-a-chip (SoC) die.

Additionally, in some examples, the electrical device 1900 may not include one or more of the components illustrated in FIG. 19, but the electrical device 1900 may include interface circuitry for coupling to the one or more components. For example, the electrical device 1900 may not include an example display 1906, but may include display interface circuitry (e.g., a connector and driver circuitry) to which the display 1906 may be coupled. In some examples, the electrical device 1900 may not include an example audio input device 1918 (e.g., microphone) or an example audio output device 1908 (e.g., a speaker, a headset, earbuds, etc.), but may include audio input or output device interface circuitry (e.g., connectors and supporting circuitry) to which the audio input device 1918 or the audio output device 1908 may be coupled.

The electrical device 1900 may include example programmable or processor circuitry 1902 (e.g., one or more processing devices). The processor circuitry 1902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1900 may include an example memory 1904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1904 may include memory that shares a die with the processor circuitry 1902. This memory may be used as cache memory and may include embedded dynamic random access memory (eDRAM) or spin transfer torque magnetic random access memory (STT-MRAM).

In some examples, the electrical device 1900 may include an example communication chip 1912 (e.g., one or more communication chips). For example, the communication chip 1912 may be configured for managing wireless communications for the transfer of data to and from the electrical device 1900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1912 may operate in accordance with other wireless protocols in other examples. The electrical device 1900 may include an example antenna 1922 to facilitate wireless communications and/or to receive other wireless communications (such as AM or FM radio transmissions).

In some examples, the communication chip 1912 may manage wired communications, such as electrical, optical, or any other suitable communication protocols (e.g., the Ethernet). As noted above, the communication chip 1912 may include multiple communication chips. For instance, a first communication chip 1912 may be dedicated to shorter-range wireless communications such as Wi-Fi or Bluetooth, and a second communication chip 1912 may be dedicated to longer-range wireless communications such as global positioning system (GPS), EDGE, GPRS, CDMA, WiMAX, LTE, EV-DO, or others. In some examples, a first communication chip 1912 may be dedicated to wireless communications, and a second communication chip 1912 may be dedicated to wired communications.

The electrical device 1900 may include example battery/power circuitry 1914. The battery/power circuitry 1914 may include one or more energy storage devices (e.g., batteries or capacitors) and/or circuitry for coupling components of the electrical device 1900 to an energy source separate from the electrical device 1900 (e.g., AC line power).

The electrical device 1900 may include the display 1906 (or corresponding interface circuitry, as discussed above). The display 1906 may include any visual indicators, such as a heads-up display, a computer monitor, a projector, a touchscreen display, a liquid crystal display (LCD), a light-emitting diode display, or a flat panel display.

The electrical device 1900 may include the audio output device 1908 (or corresponding interface circuitry, as discussed above). The audio output device 1908 may include any device that generates an audible indicator, such as speakers, headsets, or earbuds.

The electrical device 1900 may include the audio input device 1918 (or corresponding interface circuitry, as discussed above). The audio input device 1918 may include any device that generates a signal representative of a sound, such as microphones, microphone arrays, or digital instruments (e.g., instruments having a musical instrument digital interface (MIDI) output).

The electrical device 1900 may include example GPS circuitry 1916. The GPS circuitry 1916 may be in communication with a satellite-based system and may receive a location of the electrical device 1900, as known in the art.

The electrical device 1900 may include any other example output device 1910 (or corresponding interface circuitry, as discussed above). Examples of the other output device 1910 may include an audio codec, a video codec, a printer, a wired or wireless transmitter for providing information to other devices, and/or an additional storage device.

The electrical device 1900 may include any other example input device 1920 (or corresponding interface circuitry, as discussed above). Examples of the other input device 1920 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1900 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions and/or quantities that may not be exact due to manufacturing tolerances and/or other real world imperfections as will be understood by persons of ordinary skill in the art. For example, “approximately” and “about” may indicate such dimensions and/or quantities may be within a tolerance range of +/−50% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that mitigate cracking and separation of glass cores. Disclosed systems, apparatus, articles of manufacture, and methods are accordingly directed to one or more improvement(s) in the operation of a machine such as a computer or other electronic and/or mechanical device. Example glass cores disclosed herein are unibody cores and include a plurality of layers having different coefficients of thermal expansion. The variable coefficients of thermal expansion of the glass cores disclosed enable tuned thermal expansion of the glass cores, which mitigates (e.g., reduces, etc.) thermal stresses experienced by the glass cores. Example glass cores disclosed herein mitigate potential seware and related delamination associated with prior hybrid cores.

Glass cores including multiple layers and related methods are disclosed. Further examples and combinations thereof include the following:

Example 1 includes an apparatus comprising a printed circuit board, and an integrated circuit package coupled to the printed circuit board, the integrated circuit package including a die, and a glass core including a first layer having a first coefficient of thermal expansion, and a second layer having a second coefficient of thermal expansion different than the first coefficient of thermal expansion.

Example 2 includes the apparatus of any preceding example, wherein the first layer is proximate to the die and the second coefficient of thermal expansion is greater than the first coefficient of thermal expansion.

Example 3 includes the apparatus of any preceding example, wherein the first coefficient of thermal expansion is approximately equal to a third coefficient of thermal expansion of the die.

Example 4 includes the apparatus of any preceding example, wherein the second coefficient of thermal expansion is approximately equal to a fourth coefficient of thermal expansion of the printed circuit board.

Example 5 includes the apparatus of any preceding example, wherein the glass core further includes a third layer between the first layer and the second layer, the third layer having a coefficient of thermal expansion between the first coefficient of thermal expansion and the second coefficient of thermal expansion.

Example 6 includes the apparatus of any preceding example, wherein the first layer has a thickness based on a spin-on thickness capability of a glass.

Example 7 includes the apparatus of any preceding example, wherein the integrated circuit package includes an interconnect extending through the glass core, and a liner on the interconnect.

Example 8 includes the apparatus of any preceding example, wherein the integrated circuit package includes a semiconductor component embedded within the glass core.

Example 9 includes the apparatus of any preceding example, wherein the first layer abuts the second layer.

Example 10 includes an integrated circuit package including a die, and a glass core including a first region having a first coefficient of thermal expansion, and a second region having a second coefficient of thermal expansion different than the first coefficient of thermal expansion, the first region closer to the die than the second region is to the die.

Example 11 includes the integrated circuit package of any preceding example, wherein the first region is proximate to the die, the second region is distal to the die, and the second coefficient of thermal expansion is greater than the first coefficient of thermal expansion.

Example 12 includes the integrated circuit package of any preceding example, wherein the first coefficient of thermal expansion is approximately equal to a third coefficient of thermal expansion of the die.

Example 13 includes the integrated circuit package of any preceding example, wherein the glass core further includes a third region between the first region and the second region, the third region having a coefficient of thermal expansion between the first coefficient of thermal expansion and the second coefficient of thermal expansion.

Example 14 includes the integrated circuit package of any preceding example, wherein the glass core further includes a plurality of regions including the first region and the second region, the plurality of region defining a coefficient of thermal expansion gradient between the first coefficient of thermal expansion and the second coefficient of thermal expansion.

Example 15 includes the integrated circuit package of any preceding example, wherein the coefficient of thermal expansion gradient is monotonic.

Example 16 includes the integrated circuit package of any preceding example, wherein the coefficient of thermal expansion gradient is linear.

Example 17 includes an apparatus, comprising a package substrate including a glass core including a first glass layer, and a second glass layer on the first glass layer, the first glass layer having a different material composition than the second glass layer, and an electronic component embedded in at least the first glass layer.

Example 18 includes the apparatus of any preceding example, further including at least one first redistribution layer over a first side of the glass core.

Example 19 includes the apparatus of any preceding example, further including a first integrated circuit (IC) die electrically coupled to the first redistribution layer, and a second IC die electrically coupled to the first redistribution layer, wherein the electronic component includes an interconnect bridge, and wherein the interconnect bridge electrically couples the first IC die to the second IC die.

Example 20 includes the apparatus of any preceding example, further including a second redistribution layer on a second side of the glass core, and a package substrate electrically coupled to the second redistribution layer.

Example 21 includes the apparatus of any preceding example, wherein the electronic component includes at least one of a memory IC die, and Deep Trench Capacitor (DTC) IC die, a resistor IC die, a voltage regulator IC die, or an inductor.

Example 22 includes a method comprising depositing a first layer of a glass core of an integrated circuit package, the first layer having a first coefficient of thermal expansion, and depositing a second layer of the glass core on the first layer, the second layer having a second coefficient of thermal expansion different than the first coefficient of thermal expansion.

Example 23 includes the method of any preceding example, further including depositing a third layer on the first layer, the third layer having a third coefficient of thermal expansion different than the first coefficient of thermal expansion and the second coefficient of thermal expansion.

Example 24 includes the method of any preceding example, wherein the third coefficient of thermal expansion is between the first coefficient of thermal expansion and the second coefficient of thermal expansion.

Example 25 includes the method of any preceding example, wherein the depositing the first layer includes spin coating the first layer, the depositing the second layer includes spin coating the second layer, and a thickness of the first layer is based on a spin-on thickness capability of a material of the first layer.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
a printed circuit board; and
an integrated circuit package coupled to the printed circuit board, the integrated circuit package including:
a die; and
a glass core including:
a first layer having a first coefficient of thermal expansion; and
a second layer having a second coefficient of thermal expansion different than the first coefficient of thermal expansion.

2. The apparatus of claim 1, wherein the first layer is proximate to the die and the second coefficient of thermal expansion is greater than the first coefficient of thermal expansion.

3. The apparatus of claim 1, wherein the first coefficient of thermal expansion is approximately equal to a third coefficient of thermal expansion of the die.

4. The apparatus of claim 1, wherein the second coefficient of thermal expansion is approximately equal to a fourth coefficient of thermal expansion of the printed circuit board.

5. The apparatus of claim 1, wherein the glass core further includes a third layer between the first layer and the second layer, the third layer having a coefficient of thermal expansion between the first coefficient of thermal expansion and the second coefficient of thermal expansion.

6. The apparatus of claim 1, wherein the first layer has a thickness based on a spin-on thickness capability of a glass.

7. The apparatus of claim 1, wherein the integrated circuit package includes:
an interconnect extending through the glass core; and
a liner on the interconnect.

8. The apparatus of claim 1, wherein the integrated circuit package includes a semiconductor component embedded within the glass core.

9. The apparatus of claim 1, wherein the first layer abuts the second layer.

10. An integrated circuit package including:
a die; and
a glass core including:
a first region having a first coefficient of thermal expansion; and
a second region having a second coefficient of thermal expansion different than the first coefficient of thermal expansion, the first region closer to the die than the second region is to the die.

11. The integrated circuit package of claim 10, wherein the first region is proximate to the die, the second region is distal to the die, and the second coefficient of thermal expansion is greater than the first coefficient of thermal expansion.

12. The integrated circuit package of claim 10, wherein the first coefficient of thermal expansion is approximately equal to a third coefficient of thermal expansion of the die.

13. The integrated circuit package of claim 10, wherein the glass core further includes a third region between the first region and the second region, the third region having a coefficient of thermal expansion between the first coefficient of thermal expansion and the second coefficient of thermal expansion.

14. The integrated circuit package of claim 10, wherein the glass core further includes a plurality of regions including the first region and the second region, the plurality of region defining a coefficient of thermal expansion gradient between the first coefficient of thermal expansion and the second coefficient of thermal expansion.

15. The integrated circuit package of claim 14, wherein the coefficient of thermal expansion gradient is monotonic.

16. An apparatus, comprising:
a package substrate including:
a glass core including:
a first glass layer; and
a second glass layer on the first glass layer, the first glass layer having a different material composition than the second glass layer; and
an electronic component embedded in the first glass layer.

17. The apparatus of claim 16, further including at least one first redistribution layer on a first surface of the glass core.

18. The apparatus of claim 17, further including:
a first integrated circuit (IC) die electrically coupled to the first redistribution layer; and
a second IC die electrically coupled to the first redistribution layer,
wherein the electronic component includes an interconnect bridge, and
wherein the interconnect bridge electrically couples the first IC die to the second IC die.

19. The apparatus of claim 18, further including:
a second redistribution layer on a second surface of the glass core; and
a package substrate electrically coupled to the second redistribution layer.

20. The apparatus of claim 16, wherein the electronic component includes at least one of a memory IC die, and Deep Trench Capacitor (DTC) IC die, a resistor IC die, a voltage regulator IC die, or an inductor.
